(19) United States
(12) Patent Application Publication
(10) Pub. No.: US 2025/0115067 A1
(43) Pub. Date: Apr. 10, 2025

(54) FIXING APPARATUS OF IMAGE FORMING APPARATUS AND IMAGE FORMING APPARATUS

(71) Applicant: Konica Minolta, Inc., Tokyo (JP)

(72) Inventor: Masahiro MATSUO, Tokyo (JP)

(21) Appl. No.: 18/901,868

(22) Filed: Sep. 30, 2024

(30) Foreign Application Priority Data
Oct. 5, 2023 (JP) 2023-173440

(51) Int. Cl. B41J 29/377; B41J 13/08; B41M 7/00; H05K 7/20

(52) U.S. Cl. CPC B41J 29/377; B41J 13/08; B41M 7/0081; H05K 7/20145; H05K 7/20181; H05K 7/2039

(57) ABSTRACT

Provided is fixing apparatus of image forming apparatus according to the present invention. Fixing apparatus includes: conveyance section that conveys a recording medium; light emitting section that is disposed so as to face conveyance surface of conveyance section and irradiates the recording medium with UV light, the recording medium being a recording medium on which an image has been formed; mirror member that is disposed so as to surround at least a part of conveyance space formed between a light emission surface of light emitting section and conveyance surface of conveyance section and reflects the UV light, which travels from conveyance space outward, toward a front-surface side of the recording medium; and cooling section that cools mirror member from an outer-side surface of mirror member as viewed from conveyance space.

### CROSS REFERENCE TO RELATED APPLICATIONS

The present invention claims priority under 35 U.S.C. § 119 to Japanese Patent Application No. 2023-173440, filed on Oct. 5, 2023, the entire content of which is incorporated herein by reference.

### BACKGROUND

### Technological Field

The present disclosure relates to a fixing apparatus of an image forming apparatus, and the image forming apparatus.

### Description of Related Art

In the related art, there is known an image forming apparatus of an inkjet type that forms (records) an image on a recording medium (e.g., a sheet) by ejecting ink onto the recording medium from a plurality of nozzles provided in an inkjet head, and fixes the ink on the recording medium by irradiating the recording medium with ultraviolet light (hereinafter referred to as UV light) (see, for example, Patent Literature 1 (Japanese Patent Publication Laid-Open No. 2023-72335)).

The inventors of the present invention have been considering to provide a fixing apparatus, which is used in this type of image forming apparatus, with a mirror member (e.g., an aluminum material) such that the mirror member surrounds a conveyance space below a UV light emitting section (i.e., a space region formed between a light emission surface of the UV light emitting section and a conveyance surface of a conveyance section that conveys a sheet) from the viewpoints of uniformly irradiating UV light, which is emitted from the UV emitting section, in the plane of a sheet, and preventing UV light, which is emitted from the UV light emitting section, from leaking outside.

However, it has been found that although the mirror member can reflect most of the UV light emitted from the UV light emitting section and cause a sheet to absorb the UV light, the mirror member itself absorbs some of the UV light. In this respect, in a fixing apparatus in recent years, there is a tendency to increase the integrated light amount of the UV light emitted from the UV light emitting section toward a sheet in order to increase the printing speed for coping with high productivity. Therefore, in a case where the mirror member is provided without any consideration, the mirror member may be deformed due to an increase in temperature caused by excessive absorption of UV light. Then, when the mirror member is deformed in this way, the reflection direction of the UV light at the mirror member changes, and thus, it may become impossible to uniformly irradiate UV light in the plane of a sheet. That is, uneven curing of ink occurs in the plane of a sheet.

From such a viewpoint, it is a problem to be solved to study a configuration aspect of a cooling section for cooling the mirror member and suppressing deformation of the mirror member. However, in this type of fixing apparatus, it is important, in terms of obtaining satisfactory image quality, to irradiate a sheet with UV light in a state in which the temperature of the entire sheet is increased, and it is necessary to avoid a situation in which the sheet is cooled by the cooling section. Note that, in a case where a sheet is cooled by such a cooling section, for example, a cured state of ink applied onto the sheet may change, and an image different from assumption may be formed.

### SUMMARY

The present disclosure has been made in consideration of the above-described problems, and an object of the present disclosure is to provide a fixing apparatus and an image forming apparatus each capable of cooling a mirror member for UV light reflection in a pinpoint manner without cooling a recording medium.

### Solution to Problem

A main aspect of the present disclosure for solving the above-described problems is a fixing apparatus of an image forming apparatus of an inkjet type, and the fixing apparatus includes:
a conveyor that conveys a recording medium,
a light emitter that is disposed so as to face a conveyance surface of the conveyor and irradiates the recording medium, on which an image has been formed, with UV light,
a mirror member that is disposed so as to surround at least a part of a conveyance space, which is formed between a light emission surface of the light emitter and the conveyance surface of the conveyor, and reflects the UV light, which travels from the conveyance space outward, toward the recording medium; and
a cooler that cools the mirror member from an outer-side surface of the mirror member as viewed from the conveyance space.

Another aspect is an image forming apparatus that includes the fixing apparatus described above.

### BRIEF DESCRIPTION OF DRAWINGS

The advantages and features provided by one or more embodiments of the invention will become more fully understood from the detailed description given hereinbelow and the appended drawings which are given by way of illustration only, and thus are not intended as a definition of the limits of the present invention:

FIG. 1 illustrates a schematic configuration of an image forming apparatus according to an embodiment of the present invention.

FIG. 2 is a schematic diagram illustrating a configuration of a head unit according to the embodiment of the present invention.

FIG. 3 is a block diagram illustrating a main functional configuration of the image forming apparatus according to the embodiment of the present invention.

FIG. 4 illustrates a fixing section according to the embodiment of the present invention as viewed from the upper surface side.

FIG. 5 illustrates the fixing section according to the embodiment of the present invention as viewed from a lateral surface side.

FIG. 6 is a side cross-sectional view of the fixing section in the position of T1-T1′ in FIG. 4.

FIG. 7 is a side cross-sectional view of the fixing section in the position of T2-T2′ in FIG. 4.

FIG. 8 illustrates an aspect in which an air flow for cooling a mirror member flows.

FIG. 9 is a perspective view illustrating an appearance of a light emitting section.

FIG. 10 illustrates a configuration of the fixing section according to Variation 1.

FIG. 11 illustrates a configuration of the fixing section according to Variation 2.

### DETAILED DESCRIPTION OF EMBODIMENTS

Hereinafter, one or more embodiments of the present invention will be described with reference to the drawings. However, the scope of the invention is not limited to the disclosed embodiments.

### [Overall Configuration of Image Forming Apparatus of Inkjet Type]

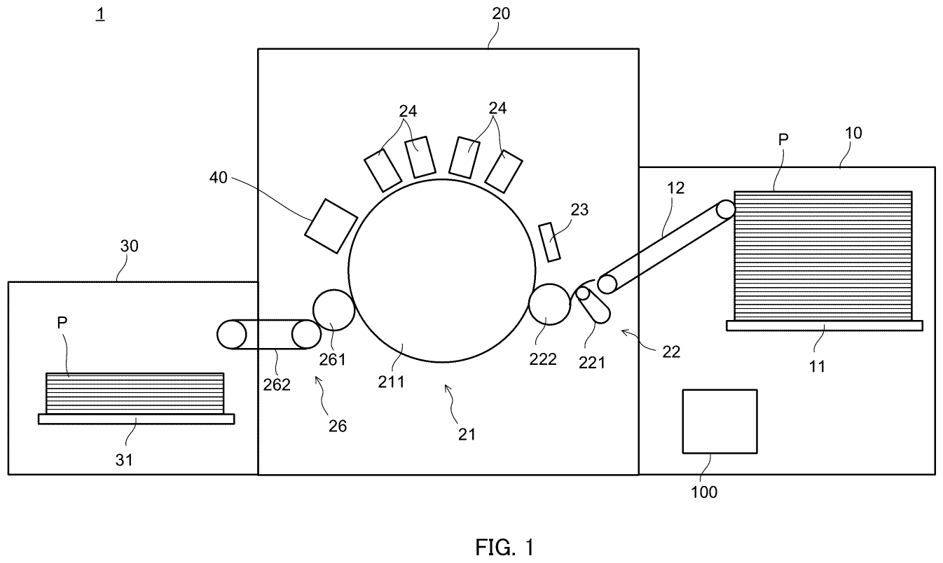

Hereinafter, the configuration of image forming apparatus 1 of an inkjet type (hereinafter, simply referred to as “image forming apparatus 1”) according to an embodiment of the present invention will be described with reference to FIG. 1 to FIG. 3.

FIG. 1 illustrates a schematic configuration of image forming apparatus 1 according to the present embodiment.

Image forming apparatus 1 includes sheet feed section 10, image forming section 20, sheet discharge section 30, fixing section 40, and control section 100. Note that, fixing section 40 corresponds to the “fixing apparatus” of the present invention.

Under the control of control section 100, image forming apparatus 1 conveys sheet P stored in sheet feed section 10 to image forming section 20, records an image by ejecting ink onto sheet P at image forming section 20, and conveys sheet P, on which the image has been recorded, to sheet discharge section 30. Specifically, image forming apparatus 1 records a color image on sheet P by outputting four colors of yellow (Y), magenta (M), cyan (C), and black (K), each with a predetermined number of gradations, on sheet P in a superposed manner.

Note that, in the present embodiment, sheet P such as plain paper or coated paper is indicated as an example of a recording medium on which an image is formed by image forming apparatus 1, but, in addition to sheet P, various sheet-like recording media on which ink having landed on the surface can be fixed, such as fabric or sheet-like resin, can be used as the recording medium to which the present disclosure is applied.

Sheet feed section 10 includes sheet feed tray 11 that stores sheet P, and medium supply unit 12 that conveys and supplies sheet P from sheet feed tray 11 to image forming section 20. Medium supply unit 12 includes a ring-shaped belt whose inner side is supported by two rollers and rotates the rollers in a state of sheet P being placed on the belt to convey sheet P from sheet feed tray 11 to image forming section 20.

Image forming section 20 includes conveyance unit 21, transfer unit 22, heating unit 23, head unit 24, and delivery unit 26.

Conveyance unit 21 holds sheet P placed on a conveyance surface of conveyance drum 211 having a cylindrical shape, and conveys sheet P on conveyance drum 211 in a conveyance direction along the conveyance surface as conveyance drum 211 rotates and circulates around a rotation axis (cylindrical axis) extending in the width direction of sheet P.

Conveyance drum 211 includes a claw section (not illustrated) and a suction section (not illustrated) which serve as holding sheet P on the conveyance surface. Sheet P is held on the conveyance surface such that an end part of sheet P is of pressed by the claw section and sheet P is sucked to the conveyance surface by the suction section.

Transfer unit 22 is provided in a position between medium supply unit 12 of sheet feed section 10 and conveyance unit 21, and holds one end of sheet P conveyed from medium supply unit 12 with swing arm section 221 to pick sheet P up, and hands over sheet P to conveyance unit 21 via transfer drum 222.

Heating unit 23 is provided between the arrangement position of transfer drum 222 and the arrangement positions of head units 24, and heats sheet P such that sheet P conveyed by conveyance unit 21 has a temperature within a predetermined temperature range. Heating unit 23 includes, for example, an infrared heater or the like, and energizes the infrared heater on the basis of a control signal supplied from control section 100 to cause the infrared heater to generate heat.

Head unit 24 ejects ink from a nozzle opening section provided in an ink ejection surface, which faces the conveyance surface of conveyance drum 211, onto sheet P at appropriate timings according to the rotation of conveyance drum 211, on which sheet P is held, to record an image.

Head unit 24 includes a plurality of inkjet heads 10, and inkjet heads 10 are disposed such that the ink (liquid droplet) ejection surface and the conveyance surface in inkjet heads 10 are separated by a predetermined distance.

In image forming apparatus 1 in the present embodiment, four head units 24 which correspond to inks of the four colors of Y, M, C, and K, respectively, are arranged at predetermined intervals in the order of the colors of Y, M, C, and K from the upstream side in the conveyance direction of sheet P. That is, head units 24 are configured to be capable of ejecting a plurality of different types of inks.

In image forming apparatus 1 in the present embodiment, head units 24 are used with the positions being fixed during image recording, and sequentially eject inks onto different positions in the conveyance direction at predetermined intervals (conveyance direction intervals) according to the conveyance of sheet P to record an image in a single pass.

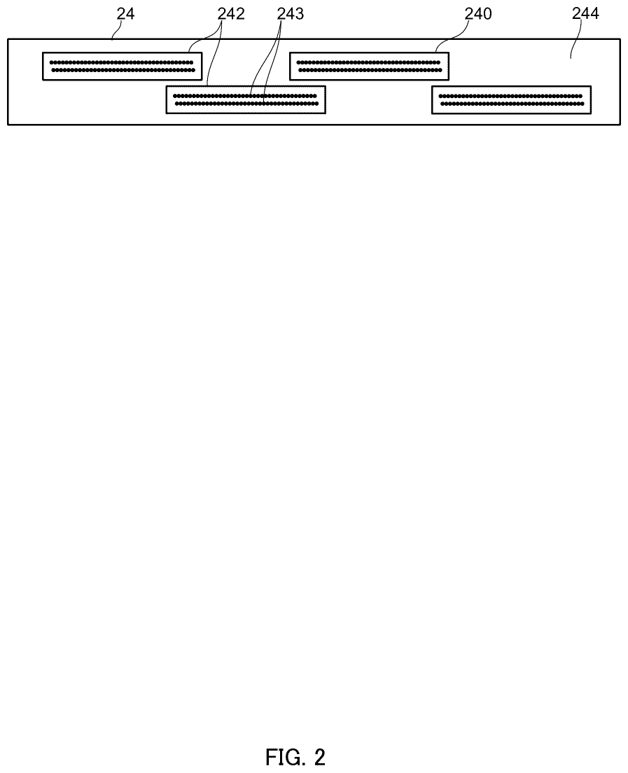

FIG. 2 is a schematic diagram illustrating a configuration of head unit 24 according to the present embodiment. FIG. 2 illustrates the surface of head unit 24, which faces the outer peripheral surface of conveyance drum 211.

Here, head unit 24 includes four inkjet heads 10 attached to attachment member 244. Each of inkjet heads 240 is provided with a plurality of image forming elements each including a pressure chamber (not illustrated) for storing ink, a piezoelectric element (not illustrated) provided on a wall surface of the pressure chamber, and nozzles 243. When a driving signal for an operation to deform the piezoelectric element is inputted, the deformation of the piezoelectric element deforms the pressure chamber to change the pressure in the pressure chamber, and the image forming elements eject inks from nozzles 243 communicating with the pressure chamber.

Four ink-jet heads 240 are arranged in a hound's-tooth check pattern such that an arrangement range in the extending direction of the nozzle row (that is, the width direction of sheet P and the direction orthogonal to the conveyance direction) is connected without a break. The arrangement range of the nozzles 13 included in head units 24 in the extending direction covers the width of a region, where an image is formed, of sheet P conveyed by conveyance drum 211, and head units 24 are used while being fixed with respect to the rotation axis of conveyance drum 211 during image formation. That is, head unit 24 forms a line head capable of ejecting ink over an image formable width in the width direction of sheet P.

Inkjet head 240 includes an ink heating section (not illustrated) that heats ink stored in inkjet head 240, and ejects ink that has been heated and turned into a sol state. When the ink in the sol state is ejected onto sheet P, ink droplets land on sheet P, and are then irradiated with UV light by fixing section, and thus, the ink quickly turns into a gel state and solidifies on sheet P.

Delivery unit 26 includes belt loop 262, which includes a ring-shaped belt whose inner side is supported by two rollers, and transfer drum 261, which has a cylindrical shape and transfers sheet P from conveyance unit 21 onto belt loop 262, and conveys sheet P, which has been transferred from conveyance unit 21 onto belt loop 262 by transfer drum 261, with belt loop 262 to send sheet P to sheet discharge section 30.

Fixing section 40 is disposed over the entire width of conveyance unit 21, and irradiates sheet P placed on conveyance unit 21 with UV light to cure and fix the ink ejected onto sheet P. Fixing section 40 is disposed, for example, between the arrangement positions of head units 24 and the arrangement position of transfer drum 261 of delivery unit 26 in the conveyance direction.

Sheet discharge section 30 includes sheet discharge tray 31 which has a plate shape and on which sheet P sent from image forming section 20 by delivery unit 26 is placed.

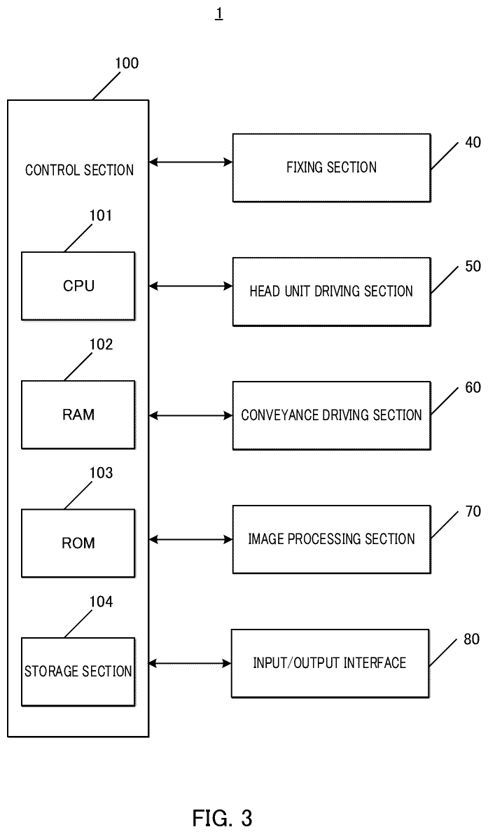

FIG. 3 is a block diagram illustrating a main functional configuration of image forming apparatus 1 according to the present embodiment. Image forming apparatus 1 according to the present embodiment includes control section 100, fixing section 40, head unit driving section 50, conveyance driving section 60, image processing section 70, and input/output interface 80.

Control section 100 includes central processing unit (CPU) 101, random access memory (RAM) 102, read only memory (ROM) 103, and storage section 104, and comprehensively controls the entire operation of image forming apparatus 1. CPU 101 reads a program corresponding to the processing content from ROM 103, develops the program in RAM 102, and centrally controls the operation of each block of image forming apparatus 1 in cooperation with the developed program. At this time, various kinds of data stored in storage section 104 are referred to. Storage section 104 is constituted by, for example, a non-volatile semiconductor memory (so-called flash memory) or a hard disk drive.

Head unit driving section 50 operates under the control of control section 100, and supplies driving signals corresponding to image data to recording elements of head units 24 at appropriate timings, thereby causing the nozzles of head units 24 to eject inks in an amount corresponding to the pixel value of the image data.

Conveyance driving section 60 operates under the control of control section 100, and supplies a driving signal to a conveyance drum motor provided in conveyance drum 211 to rotate conveyance drum 211 at a predetermined speed and timing. In addition, conveyance driving section 60 supplies driving signals to motors for operating medium supply unit 12, transfer unit 22, and delivery unit 26 based on a control signal supplied from control section 100 to cause sheet P to be supplied to and discharged from conveyance unit 21.

Image processing section 70 performs predetermined image processing on image data inputted from input/output interface 80 and causes storage section 44 to store the obtained image data. The image processing includes correction processing for correcting image data as well as color conversion processing, tone correction processing, pseudo halftone processing, and the like.

Input/output interface 80 is connected to an input/output interface of an external apparatus (e.g., a personal computer) and mediates transmission and reception of data between control section 100 and the external apparatus. Input/output interface 80 includes, for example, various serial interfaces, various parallel interfaces, or a combination of these interfaces.

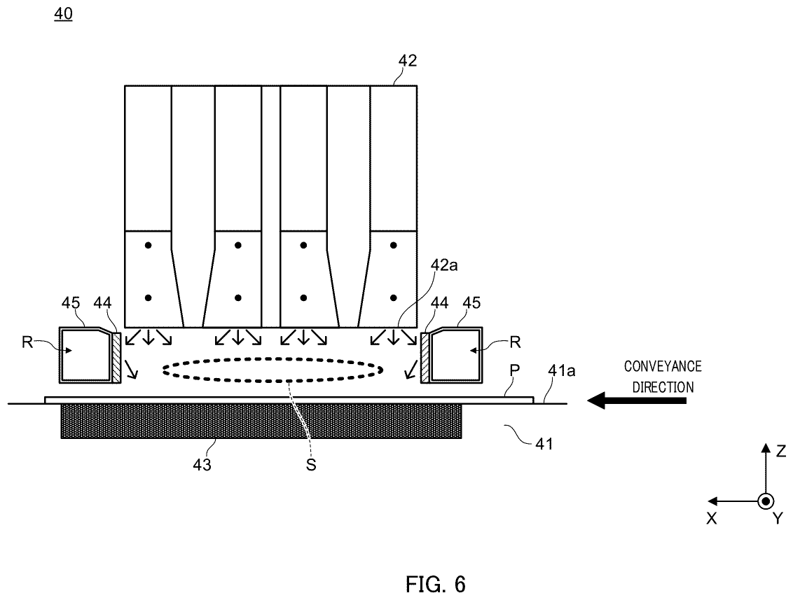

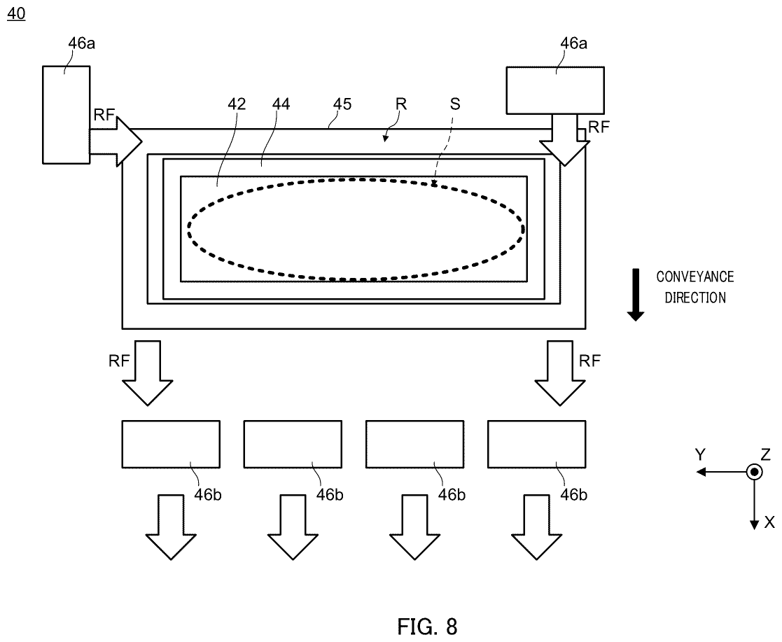

Fixing section 40 operates under the control of control section 100, emits UV light at a predetermined irradiation intensity from light irradiation section 42 (see FIG. 6) included in fixing section 40, and irradiates sheet P, on which an image has been formed, with the UV light to cure and fix the ink ejected onto sheet P. Furthermore, fixing section 40 raises the temperature of heater 43 (see FIG. 6) included in fixing section 40 to heat sheet P to a predetermined temperature. Further, fixing section 40 controls operations of fans 46a and 46b (see FIG. 8) included in fixing section 40.

### [Configuration of Fixing Section 40]

Hereinafter, a configuration of fixing section 40 according to the present embodiment will be described.

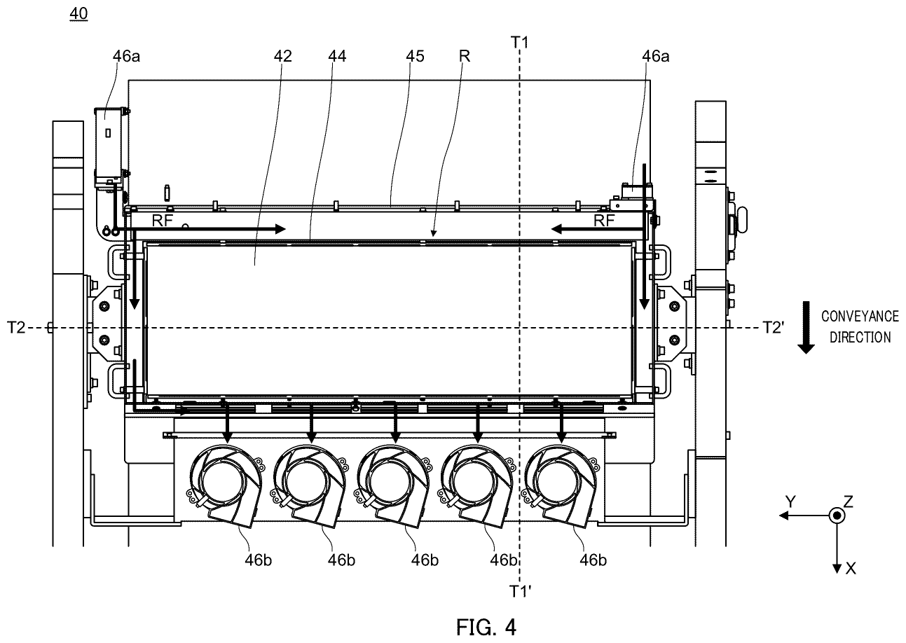

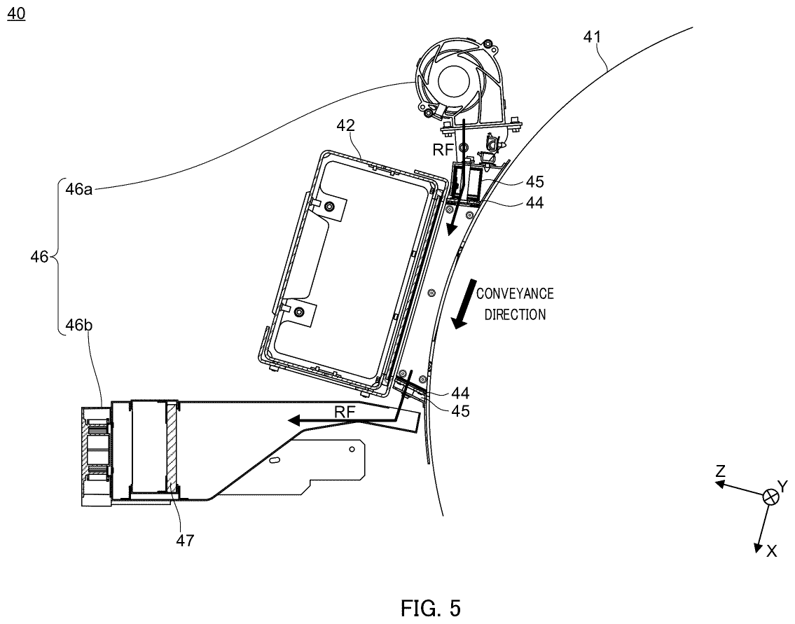

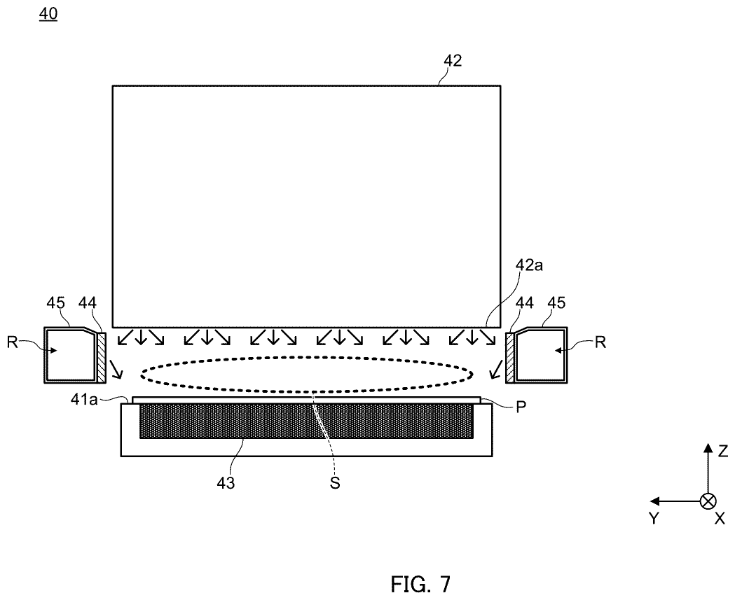

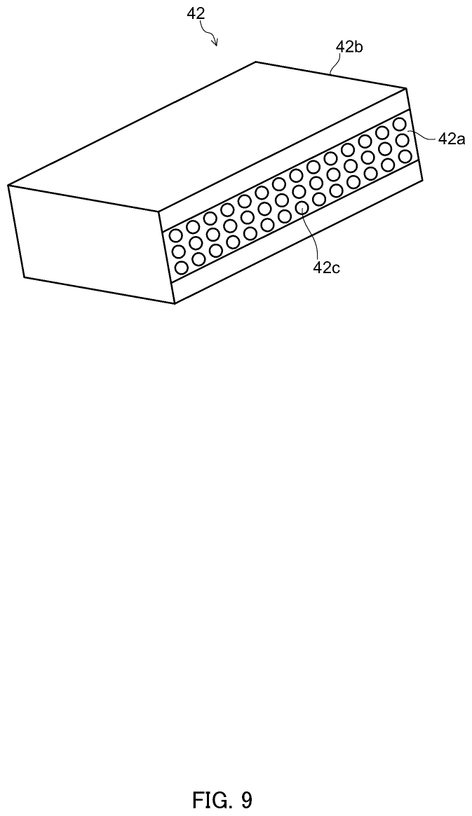

FIG. 4 to FIG. 9 illustrate the configuration of fixing section 40. FIG. 4 illustrates fixing section 40 as viewed from the upper surface side. FIG. 5 illustrates fixing section 40 as viewed from a lateral surface side. FIG. 6 is a side cross-sectional view of fixing section 40 in the position of T1-T1′ in FIG. 4. FIG. 7 is a side cross-sectional view of fixing section 40 in the position of T2-T2′ in FIG. 4. FIG. 8 illustrates an aspect in which air flow RF for cooling mirror member 44 flows, and corresponds to a diagram of fixing section 40 as viewed from the upper surface side. FIG. 9 is a perspective view illustrating an appearance of light emitting section 42.

Note that, FIG. 4 to FIG. 8 are illustrated with a common orthogonal coordinate system (X, Y, Z) in order to clarify the positional relationship of each configuration. That is, in FIG. 4 to FIG. 8, the conveyance direction of sheet P is indicated by a plus X-axis direction, the width direction of sheet P is indicated by a Y-axis direction, and the direction orthogonal to the X-axis and the Y-axis is indicated by a Z-axis direction.

Fixing section 40 includes conveyance section 41, light emitting section 42, heater 43, mirror member 44, duct forming member 45, and cooling fan 46.

Conveyance section 41 conveys sheet P in a predetermined conveyance direction in a state in which sheet P is placed on conveyance surface 41a. Conveyance section 41 according to the present embodiment is constituted by conveyance drum 211 described above (see FIG. 1). Conveyance section 41 includes, for example, a sheet fixing section (not illustrated) that conveys sheet P in a state of being in close contact with conveyance surface 41a by sucking or chucking sheet P from the rear surface side.

Note that, conveyance section 41 may be constituted separately from conveyance drum 211 of conveyance unit 21, or may be constituted by a conveyance belt instead of the conveyance drum.

Light emitting section 42 irradiates an ink application region on sheet P, on which an image has been formed and which is conveyed by conveyance section 41, with UV light, heats and dries the ink on sheet P, and fixes the ink on sheet P. The UV light emitted by light emitting section 42 is, for example, UV light having a wavelength (e.g., 400 nm) corresponding to the light absorbing wavelength of the ink.

Light emitting section 42 is disposed in a position facing conveyance surface 41a of conveyance section 41 while being separated from conveyance surface 41a. Conveyance space S for sheet P is formed between emission surface 42a of light emitting section 42 and conveyance surface 41a of conveyance section 41.

Light emitting section 42 includes a plurality of emittance elements 42c arranged along the conveyance direction in housing 1b. Light emitting section 42 according to the present embodiment is constituted by a plurality of light emitting diodes arranged in a lattice pattern (that is, arranged along the X-axis direction and the Y-axis direction) on emittance surface 42a (see FIG. 9). Light emitting section 42 is in a state of uniformly emitting light along emittance surface 42a as a whole by the light emitting diodes emitting light at the same luminance.

Note that, the plurality of emittance elements 42c may be configured to emit UV light having the same wavelength, but may be configured to emit UV light having different wavelengths suitable for the respective ink colors. Further, emittance elements 42c may be constituted by laser diodes instead of the light emitting diodes.

The energy intensity of the UV light emitted by light emitting section 42 is preferably as high as possible, and is preferably equal to or greater than 4 W/cm². Thus, the ink drying efficiency can be increased.

In light emitting section 42, for example, emittance surface 42a of light emitting section 42 is disposed substantially parallel to conveyance surface 41a of conveyance section 41 such that the UV light outputted from each of the plurality of emittance elements 41c is efficiently irradiated onto each position of sheet P. Note that, the length of space region S (conveyance space S) between emittance surface 42a of light emitting section 42 and conveyance surface 41a of conveyance section 41 is, for example, equal to or greater than 10 mm and less than 30 mm.

Heater 43 is disposed on the rear-surface side of conveyance surface 41a of conveyance section 41, and heats sheet P in a position in which sheet P is irradiated with the UV light by heat conduction from the rear-surface side of sheet P. That is, when sheet P is irradiated with the UV light from light emitting section 42, heater 43 simultaneously heats sheet P by heat conduction from the rear-surface side. Since this makes it possible to cure ink by the UV light in a state in which the temperature of sheet P in its entirety is raised to a certain temperature, it is possible to stabilize the cured aspect of the ink in the plane of sheet P and to improve the image quality of the image formed on sheet P.

As illustrated in FIG. 6 and FIG. 7, for example, heater 43 is constituted by a hot plate or a band heater (illustrations thereof are omitted in FIG. 4 and FIG. 5) disposed so as to heat sheet P by heat conduction via conveyance surface 41a of conveyance section 41 (i.e., the front surface of conveyance drum 211) in a position facing light emitting section 42. Heater 43 may be configured to come into contact with sheet P to heat sheet P directly.

Mirror member 44 is disposed so as to surround at least a part of conveyance space S below light emitting section 42 (which indicates a space region formed between emission surface 42a of light emitting section 42 and conveyance surface 41a of conveyance section 41; the same applies hereinafter), and reflects the UV light, which travels from conveyance space S described above outward, toward the front-surface side of sheet P.

Mirror member 44 is formed of, for example, a plate member whose reflection surface is formed of an aluminum member. Then, mirror member 44 is disposed such that, in a state in which the reflection surface faces a side of conveyance space S, the reflection surface and conveyance surface 41a of conveyance section 41 (i.e., the front surface of sheet P) form a substantially right angle. The shape and inclination angle of the reflection surface of mirror member 44 are adjusted such that the UV light is uniformly irradiated in the plane of sheet P.

Note that, as illustrated in FIG. 8, mirror member 44 is preferably disposed so as to surround the entire periphery (four directions of the positive X-axis direction side, the negative X-axis direction side, the positive Y-axis direction side, and the negative Y-axis direction side of conveyance space S in FIG. 8) of conveyance space S below light emitting section 42. Thus, for most of the UV light emitted from light emitting section 42, the UV light can be suppressed from leaking out of conveyance space S, and the UV light can be utilized for curing the ink on the front surface of sheet P.

Mirror member 44 uniformly irradiates UV light, which is emitted from light emitting section 42, in the plane of sheet P, and prevents the UV light from leaking outside of conveyance space S. However, as described above, in fixing section 40 in recent years, there is a tendency to increase the integrated light amount of the UV light emitted from light emitting section 42, and mirror member 44 may be deformed due to an increase in temperature caused by excessive absorption of the UV light.

Therefore, in fixing section 40 according to the present embodiment, a “cooling section” constituted by duct forming member 45 and cooling fans 46a and 46b is provided in order to suppress a temperature rise in mirror member 44.

Note that, the cooling section is configured to cool mirror member 44 from an outer-side surface of mirror member 44 as viewed from conveyance space S such that an air flow as a refrigerant does not hit sheet P passing through conveyance space S. Hereinafter, a specific configuration of the cooling section will be described.

Duct forming member 45 is disposed so as to form air flow path R (e.g., a duct having a substantially rectangular short-side cross section) along the outer-side surface of mirror member 44 as viewed from conveyance space S (see FIG. 8). In air flow path R as such, air as a refrigerant (air flow RF in FIG. 8) flows by operations of cooling fans 46a and 46b. Thus, in a case where the temperature of mirror member 44 rises due to absorption of UV light, heat generated at mirror member 44 can be released to outside via air flow path R.

Duct forming member 45 is formed of, for example, a material having a good heat dissipation characteristic (for example, an aluminum material), and is disposed adjacent to the outer-side surface of mirror member 1. Then, duct forming member 45 absorbs heat that is generated at mirror member 44 by heat conduction and dissipates the heat into air flow path R formed by duct forming member 45. Thus, mirror member 44 serving as a heat source can be cooled intensively.

Note that, in the present embodiment, duct forming member 45 is disposed so as to surround the entire circumference of conveyance space S to form air flow path R along the outer-side surface of mirror member 44 (see FIG.; 8). Thus, the heat dissipation performance of mirror member 44 is further enhanced.

Furthermore, in the present embodiment, duct forming member 45 is formed integrally with a support member that supports light emitting section 42 (see FIG. 5). The support member supporting light emitting section 42 is, for example, disposed so as to be a cover covering housing 42a of light emitting section 42 from above, and supports light emitting section 42 from above. In this way, since duct forming member 45 and the support member are integrally formed, it is possible to reduce the number of parts when manufacturing fixing section 40 and to suppress complication of the manufacturing process.

Cooling fans 46a and 46b cause a gas to flow through air flow path R formed in duct forming member 45. Fixing section 40 according to the present embodiment includes, as cooling fans 46a and 46b, blower fan 46a that blows air from the upstream side of air flow path R to cause the gas to flow through air flow path R, and suction fan 46b that performs suction from the downstream side of air flow path R to cause the gas to flow through air flow path R.

As a result, an air flow from the upstream side in the conveyance direction to the downstream side in the conveyance direction (see air flow RF in FIG. 8) is constantly formed in air flow path R. Formation of such an air flow (see air flow RF in FIG. 8) leads to a state in which the heat generated in mirror member 44 is effectively carried together with the air outside. That is, air flow RF in air flow path R contributes to further enhancing the heat dissipation performance of mirror member 44.

Note that, fixing section 40 according to the present embodiment makes it possible to ensure a sufficient air flow volume of air flow RF in air flow path R by using both blower fan 46a and suction fan 46b as cooling fans 46a and 46b. In addition, such a configuration causes air flow RF generated by cooling fans 46a and 46b to be air flowing from the upstream side in the conveyance direction to the downstream side in the conveyance direction, and thus, it is possible to suppress turning up of the front portion of sheet P (for example, a turning-up phenomenon due to a lifting force) due to the flow of such air when sheet P is chucked.

### [Effects]

As described above, fixing section 40 of image forming apparatus 1 according to the present embodiment includes:
conveyance section 41 that conveys sheet P;
light emitting section 42 that is disposed so as to face conveyance surface 41a of conveyance section 41 and irradiates sheet P, on which an image has been formed, with UV light;
mirror member 44 that is disposed so as to surround at least a part of conveyance space S, which is formed between emission surface 42a of light emitting section 42 and conveyance surface 41a of conveyance section 41, and reflects the UV light, which travels from conveyance space S outward, toward a front-side surface of sheet P; and
cooling section 45, 46a, 46b that cools mirror member 44 from an outer-side surface of mirror member 44 as viewed from conveyance space S

Fixing section 40 according to the present embodiment makes it possible to cool mirror member 44 for UV light reflection in a pinpoint manner without cooling sheet P to be fixed and suppress deformation of mirror member 44. Thus, it is possible to perform uniform UV irradiation in the plane of sheet P, and uneven curing of ink in the plane of sheet P can be reduced. In addition, since it is also possible to suppress a change in the cured state of the ink applied onto sheet P due to an insufficient temperature rise in sheet P, it is possible to suppress deterioration in image quality.

### (Variation 1)

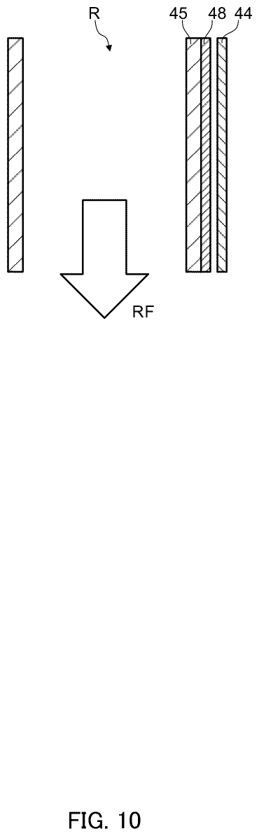

FIG. 10 illustrates a configuration of fixing section 40 according to Variation 1.

As described in the above embodiment, duct forming member 45 is disposed, for example, adjacent to the outer-side surface of mirror member 44 as viewed from conveyance space S, and forms air flow path R along the outer-side surface. From such a viewpoint, in fixing section 40 according to Variation 1, heat dissipation sheet 48 formed of an elastic member (e.g., a rubber material) is disposed between mirror member 44 and duct forming member 45. Note that, FIG. 10 illustrates, on an enlarged scale, only a region where mirror member 44 and duct forming member 45 are arranged adjacent to each other (illustrations of the other configurations of fixing section 40 are omitted).

That is, the heat dissipation characteristic from mirror member 44 to outside depends on the smoothness of heat transfer from mirror member 44 to air flow path R. Heat dissipation sheet 48 is disposed from such a viewpoint, and heat dissipation sheet 48 is interposed between mirror member 44 and duct forming member 45, and thus, it is possible to ensure adhesion between mirror member 44 and duct forming member 45 and support smooth heat conduction from mirror member 44 to duct forming member 45. That is, such a configuration makes it possible to improve the heat dissipation characteristic from mirror member 44 to the outside.

Having said that, duct forming member 45 may not necessarily include a member that abuts on the outer-side surface of mirror member 44. That is, duct forming member 45 may form air flow path R such that air flow path R covers the outer-side surface of mirror member 44. In this case, heat dissipation sheet 48 according to the present variation is not necessary.

### (Variation 2)

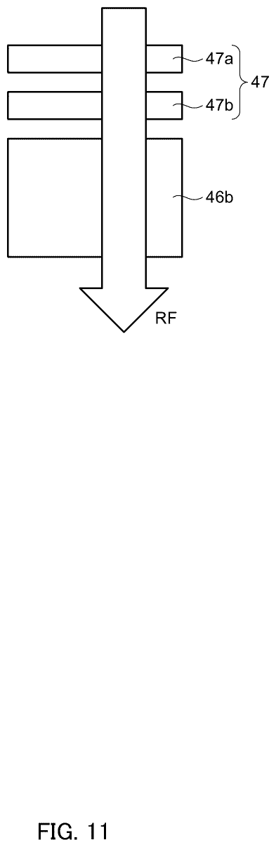

FIG. 11 illustrates a configuration of fixing section 40 according to Variation 2.

Fixing section 40 according to Variation 2 has a configuration in which filter 47 is disposed on the downstream side of air flow path R and filters the gas flowing from the inside of air flow path R toward suction fan 46b. Note that, FIG. 11 illustrates an aspect in which filter 47 is attached to a suction port of suction fan 46b (illustrations of the other configurations of fixing section 40 are omitted).

Such filter 47 is preferably, in particular, a filter having a function of removing ink mist or a filter having a function of removing an abnormal odor (ink odor, ozone odor, or the like).

Thus, it is possible to remove ink mist floating in the air inside image forming apparatus 1 and remove an abnormal odor (for example, ink odor and ozone odor) by using the suction of cooling fan 46b.

Note that, as illustrated in FIG. 11, it is more preferably configured such that filter 47 includes both first filter 47a having a function of removing ink mist and second filter 47b having a function of removing an abnormal odor (for example, ink odor and ozone odor), and first filter 47a is disposed on the upstream side of second filter 47b. In this case, by disposing first filter 47a on the upstream side of second filter 47b, it is possible to suppress clogging of second filter 47b due to ink mist.

### OTHER EMBODIMENTS

Note that, the present invention is not limited to the embodiment described above, and is applicable to various modification aspects.

In the embodiment described above, an aspect in which mirror member 44 surrounds the entire periphery of conveyance space S has been indicated, but, as the configuration of fixing section 40 according to the present invention, mirror member 44 may be disposed so as to surround only a part of conveyance space S (e.g., only two directions of the positive Y-axis direction side and the negative Y-axis direction side of conveyance space S). Similarly, duct forming member 45 may form air flow path R such that air flow path R surrounds only a part of the periphery of conveyance space S. Alternatively, duct forming member 45 may form air flow path R along only a part of the outer-side surface of mirror member 44.

In addition, in the embodiment described above, an aspect in which both blower fan 46a and suction fan 46b are included as cooling fans 46a and 46b has been indicated, but, as the configuration of fixing section 40 according to the present invention, only blower fan 46a that blows air from the upstream side of air flow path R to cause the gas to flow through air flow path R may be provided or only suction fan 46b that performs suction from the downstream side of air flow path R to cause the gas to flow through air flow path R may be provided.

In addition, in the embodiment described above, an aspect in which conveyance section 41 is constituted by a conveyance drum has been described, but, as the configuration of fixing section 40 according to the present invention, conveyance section 41 may be constituted by a conveyance belt.

Although embodiments of the present invention have been described and illustrated in detail, the disclosed embodiments are made for purpose of illustration and example only and not limitation. The scope of the present invention should be interpreted by terms of the appended claims.

### INDUSTRIAL APPLICABILITY

The fixing apparatus according to the present disclosure makes it possible to cool a mirror member for UV light reflection in a pinpoint manner without cooling a recording medium.

### REFERENCE SIGNS LIST

1 Image forming apparatus
10 Sheet feed section
20 Image forming section
30 Sheet discharge section
40 Fixing section
41 Conveyance section
41a Conveyance surface
42 Light emitting section
42a Emittance surface
42b Housing
42c Emittance element
43 Heater
44 Mirror member
45 Duct forming member
46a, 46b Cooling fan
100 Control section
P Sheet (recording medium)
S Conveyance space
R Air flow path
RF Air flow

What is claimed is:

1. A fixing apparatus of an image forming apparatus of an inkjet type, the fixing apparatus comprising:
a conveyor that conveys a recording medium;
a light emitter that is disposed so as to face a conveyance surface of the conveyor and irradiates the recording medium with UV light, the recording medium being a recording medium on which an image has been formed;
a mirror member that is disposed so as to surround at least a part of a conveyance space and reflects the UV light toward the recording medium, the conveyance space being formed between a light emission surface of the light emitter and the conveyance surface of the conveyor, the UV light traveling from the conveyance space outward; and
a cooler that cools the mirror member from an outer-side surface of the mirror member as viewed from the conveyance space.

2. The fixing apparatus according to claim 1, wherein
the cooler is constituted by a duct forming member and a cooling fan, the duct forming fan forming an air flow path along the outer-side surface of the mirror member, the cooling fan that causes a gas to flow through the air flow path.

3. The fixing apparatus according to claim 2, wherein
the cooling fan is a blower fan that blow air from an upstream side of the air flow path to cause the gas to flow through the air flow path.

4. The fixing apparatus according to claim 2, wherein
the cooling fan is a suction fan that performs suction from a downstream side of the air flow path to cause the gas flow through the air flow path.

5. The fixing apparatus according to claim 2, wherein
the cooling fan is constituted by a blower fan and a suction fan, the blower fan blowing air from an upstream side of the air flow path to cause the gas to flow through the air flow path, the suction fan performing suction from a downstream side of the air flow path to cause the gas to flow through the air flow path.

6. The fixing apparatus according to claim 2, wherein
the duct forming member is formed integrally with a support member that supports the light emitter.

7. The fixing apparatus according to claim 2, wherein:
the duct forming member is disposed adjacent to the outer-side surface of the mirror member, and
a heat dissipation sheet formed of an elastic member is interposed between the mirror member and the duct forming member.

8. The fixing apparatus according to claim 2, wherein
the mirror member is disposed so as to surround an entire circumference of the conveyance space.

9. The fixing apparatus according to claim 2, wherein
the duct forming member is disposed so as to surround an entire circumference of the conveyance space and form the air flow path along the outer-side surface of the mirror member.

10. The fixing apparatus according to claim 1, further comprising a heater that is disposed on a rear-surface side of the conveyance surface of the conveyor and heats the recording medium from the rear-surface side.

11. The fixing apparatus according to claim 4, further comprising a filter that is disposed on the downstream side of the air flow path and filters the gas, the gas flowing from inside of the air flow path toward the suction fan.

12. The fixing apparatus according to claim 11, wherein
the filter has a function of removing ink mist.

13. The fixing apparatus according to claim 11, wherein
the filter has a function of removing an abnormal odor.

14. The fixing apparatus according to claim 11, wherein
the filter includes a first filter and a second filter, and the first filter is disposed on an upstream side of the second filter, the first filter having a function of removing ink mist, the second filter having a function of removing an abnormal odor.

15. An image forming apparatus, comprising the fixing apparatus according to claim 1.
